(19) United States
(12) Patent Application Publication
(10) Pub. No.: US 2018/0294178 A1
(43) Pub. Date: Oct. 11, 2018

(54) METHOD OF MANUFACTURING ULTRA THIN WAFERS

(71) Applicant: Intel Corporation, Santa Clara, CA (US)

(72) Inventor: Xavier F. Brun, Chandler, AZ (US)

(21) Appl. No.: 15/762,453

(22) PCT Filed: Sep. 23, 2015
(86) PCT No.: PCT/US2015/051718

§ 371 Date: Mar. 22, 2018

(51) Int. Cl. H01L 21/683; H01L 21/78; H01L 23/544; H01L 23/00; H01L 21/67; H01L 21/673

(52) U.S. Cl. CPC H01L 21/6835; H01L 21/78; H01L 23/544; H01L 24/94; H01L 2223/5446; H01L 21/67333; H01L 2221/68381; H01L 2221/68327; H01L 21/67144

(57) ABSTRACT

Some example forms relate to a method of manufacturing ultra-thin wafers. The method includes attaching a wafer that includes a plurality of electronic components to a carrier wafer that includes an adhesive; segregating the plurality of dice into individual electronic components, wherein segregating the plurality of dice into individual electronic components includes thinning and dicing the wafer; performing at least one of coating, scribing or marking any of the individual electronic components that form the wafer; and removing the plurality of electronic components from the carrier wafer, wherein removing the plurality of electronic components from the carrier wafer includes at least one of exposing the carrier to ultraviolet radiation or raising the temperature of the wafer.

### BACKGROUND

There are a variety of manufacturing difficulties that are associated with fabricating electronic components that include ultra-thin and highly warped wafers. As an example, when manufacturing electronic components that include through silicon vias and/or highly warped ultra-thin wafers (e.g., 40 microns or less), conventional processes typically include mounting the wafer or separated electronic components on a film frame (i.e., dicing or mounting tape) before the individual electronic components are picked from the film frame. The use of a film frame adds unwanted costs associated with producing electronic components that include through silicon vias and/or ultra-thin wafers.

### BRIEF DESCRIPTION OF THE DRAWINGS

FIG. 1 is a schematic side view illustrating an initial portion of an example method of manufacturing an ultra-thin wafer.

FIG. 2 is a schematic side view similar to FIG. 1 illustrating another portion of the example method of manufacturing an ultra-thin wafer.

FIG. 3 is a schematic side view similar to FIG. 2 illustrating yet another portion of the example method of manufacturing an ultra-thin wafer.

FIG. 4 is a schematic side view similar to FIG. 3 illustrating still another portion of the example method of manufacturing an ultra-thin wafer.

FIG. 5 is a schematic side view similar to FIG. 4 illustrating another portion of the example method of manufacturing an ultra-thin wafer.

FIG. 6 is a schematic side view similar to FIG. 5 illustrating yet another portion of the example method of manufacturing an ultra-thin wafer.

FIG. 7 is a schematic side view similar to FIG. 6 illustrating an alternative portion of the example method that is shown in FIG. 5.

FIG. 8 is a schematic side view similar to FIG. 5 illustrating an example separated ultra-thin wafer mounted on a substrate.

FIG. 9 is a schematic side view similar to FIG. 5 illustrating another portion of the example method of manufacturing an ultra-thin wafer.

FIG. 10 is a schematic side view similar to FIG. 5 illustrating an alternative portion of the example method of manufacturing an ultra-thin wafer.

FIG. 11 is a flow diagram illustrating an example method of manufacturing an ultra-thin wafer.

FIG. 12 is block diagram of an electronic apparatus that utilizes the methods described herein.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Orientation terminology, such as “horizontal,” as used in this application is defined with respect to a plane parallel to the conventional plane or surface of a wafer or substrate, regardless of the orientation of the wafer or substrate. The term “vertical” refers to a direction perpendicular to the horizontal as defined above. Prepositions, such as “on,” “side” (as in “sidewall”), “higher,” “lower,” “over,” and “under” are defined with respect to the conventional plane or surface being on the top surface of the wafer or substrate, regardless of the orientation of the wafer or substrate.

The methods described herein may permit manufacturing processes that pick electronic components directly from a temporary carrier. The ability to pick electronic components directly from a temporary carrier instead of a film frame may simplify the processes and eliminate the need for dicing (or mount) tape.

In addition, the methods described herein may be able to handle ultra-thin warped wafers (e.g., greater than 40 mm) and highly warped wafers (e.g., less than 50 micrometers). The methods described herein may also eliminate the need for a doubled-sided pick (e.g., a needleless ejector pin with collet or needle ejector with collet) and enable single-sided pick of electronic components without the use of dicing tape.

The methods described herein may also reduce the risk of thin wafer cracking by having temporary support for all electronic component preparation steps. Therefore, the methods may eliminate the risk of electronic component edge chipping due to film frame sagging, extension or peel. In addition, the damage risk due to ejector pin or needleless ejector activation may be eliminated when handling ultra-thin dies.

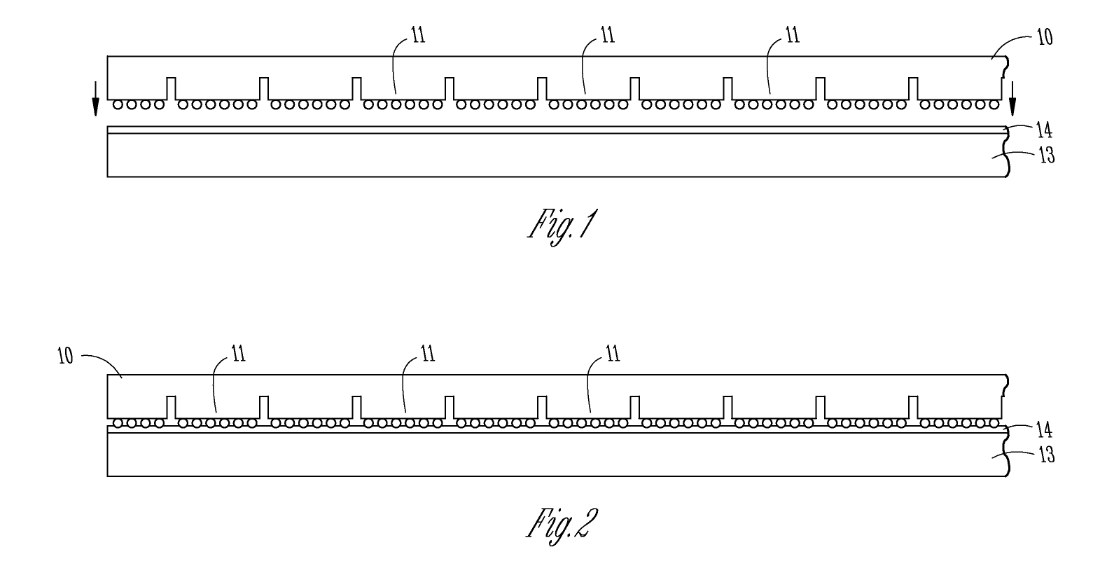

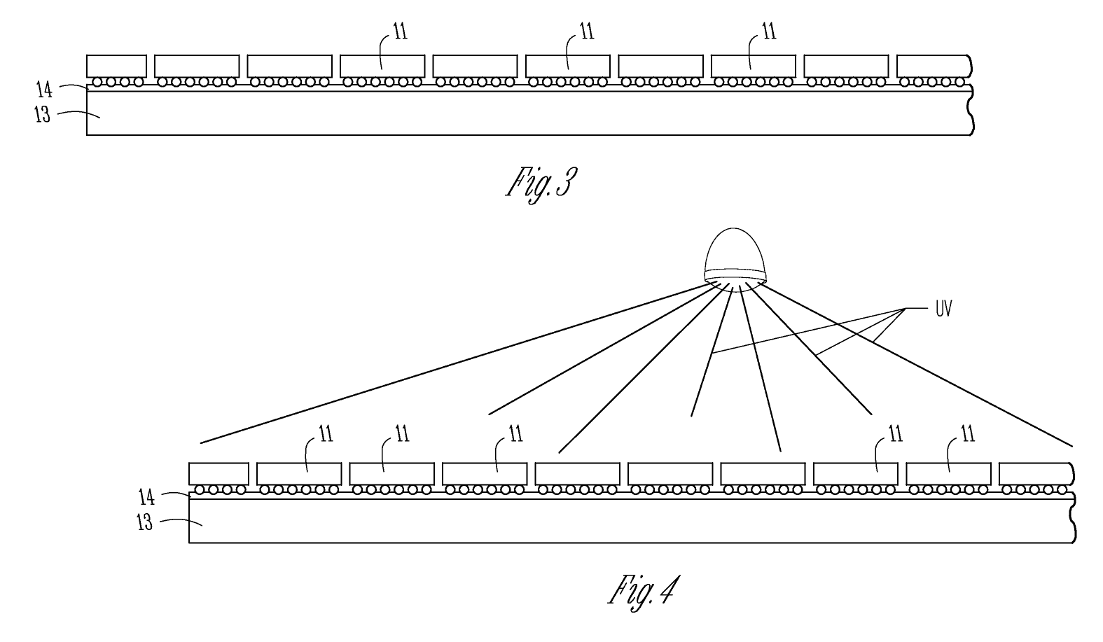

FIGS. 1-7 and 9-10 are schematic views illustrating various portions and variations of an example method (100) of manufacturing an ultrathin wafer. The method (100) includes (110) attaching a wafer (10) that includes a plurality of electronic components (11) to a carrier wafer (13) that includes an adhesive (14) (see FIGS. 1 and 2).

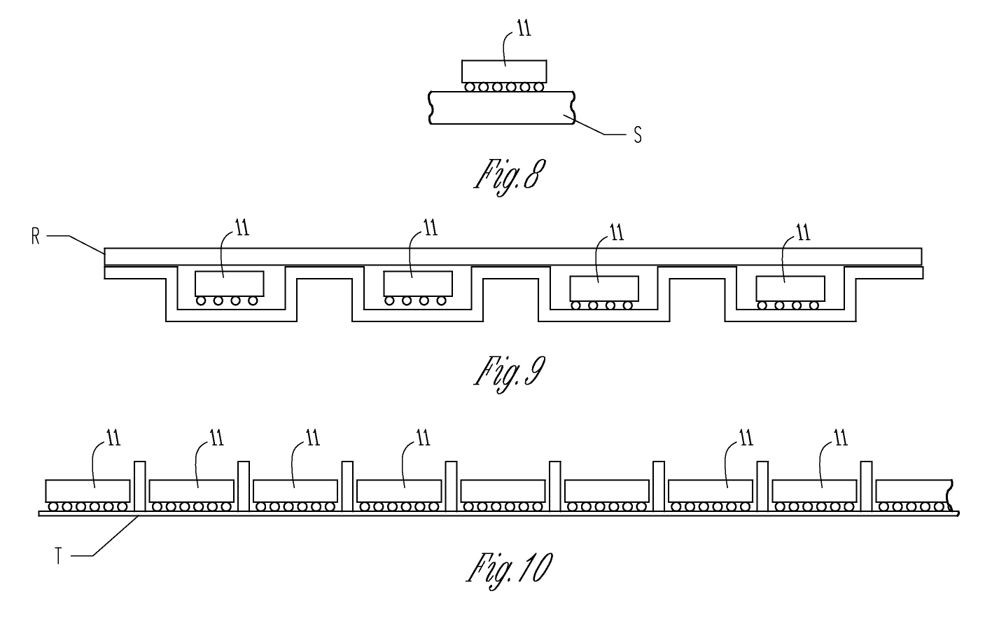

The method (100) further includes (120) segregating the plurality of electronic components (11) into individual electronic components (11) (see FIG. 3). The method further includes (130) removing the plurality of electronic components (11) from the carrier wafer (13). FIG. 5 shows the electronic components (11) being removed individually. FIG. 7 shows an example form where the electronic components have been simultaneously removed and collectively moved to an example cleaning station.

In some forms, (120) segregating the plurality of electronic components (11) into individual electronic components (11) includes dicing the wafer (10) and/or thinning the wafer (10). It should be noted that any process for separating the plurality of electronic components (11) to individual electronic components (11) that is known now, or discovered in the future, may be used to separate the electronic components (11).

The method may further include coating, scribing or marking one, some, or all of the individual electronic components (11) that form the wafer (10). The electronic components may be individually, or collectively, subjected to other processes. As examples, some of these processes include, but are not limited to, stress-relief and/or component validation.

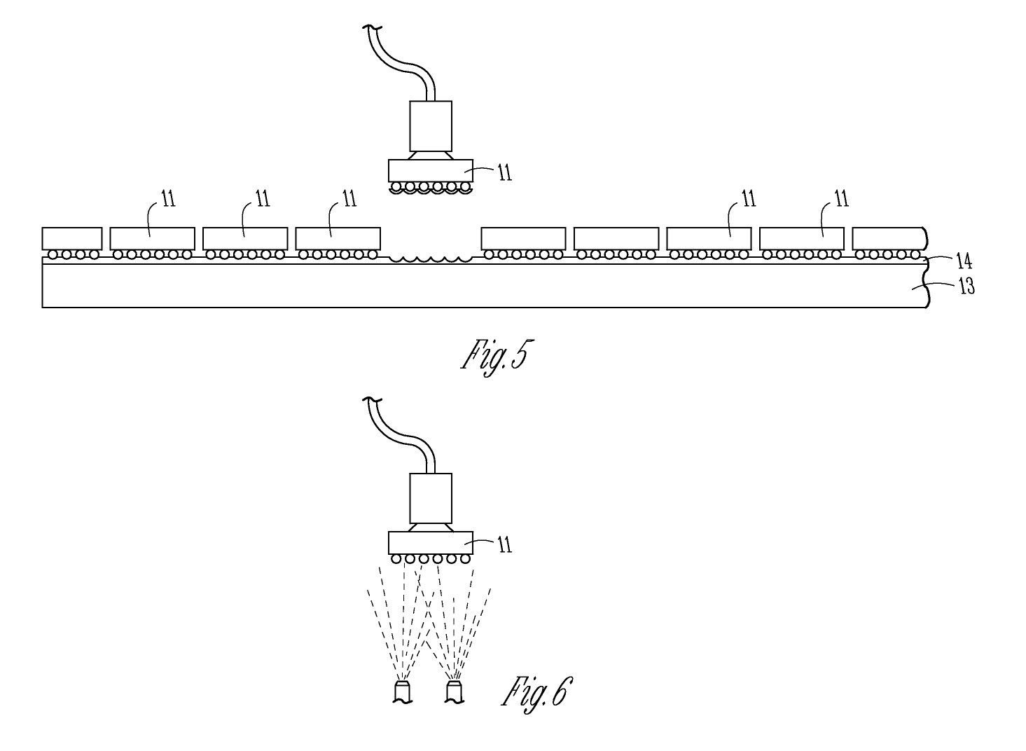

As shown in FIG. 4, (130) removing the plurality of electronic components (11) from the carrier wafer (13) may include exposing the carrier wafer (13) to ultraviolet radiation. In other forms of the method (100), (120) removing the plurality of electronic components (11) from the carrier wafer (13) may include raising the temperature of the wafer (10).

When using ultraviolet radiation to reduce the adhesion between the plurality of electronic components (11) and the carrier wafer (13), the ultraviolet radiation may cross-link the adhesive in order to reduce the adhesive capability of the adhesive (14). When the temperature of the wafer (10) is raised to an efficient level (e.g., for thermoplastic or wax adhesives), the heat supplied to the adhesive (14) may reduce the viscosity of the adhesive in order to permit separating the plurality of electronic components (11) from the carrier wafer 13.

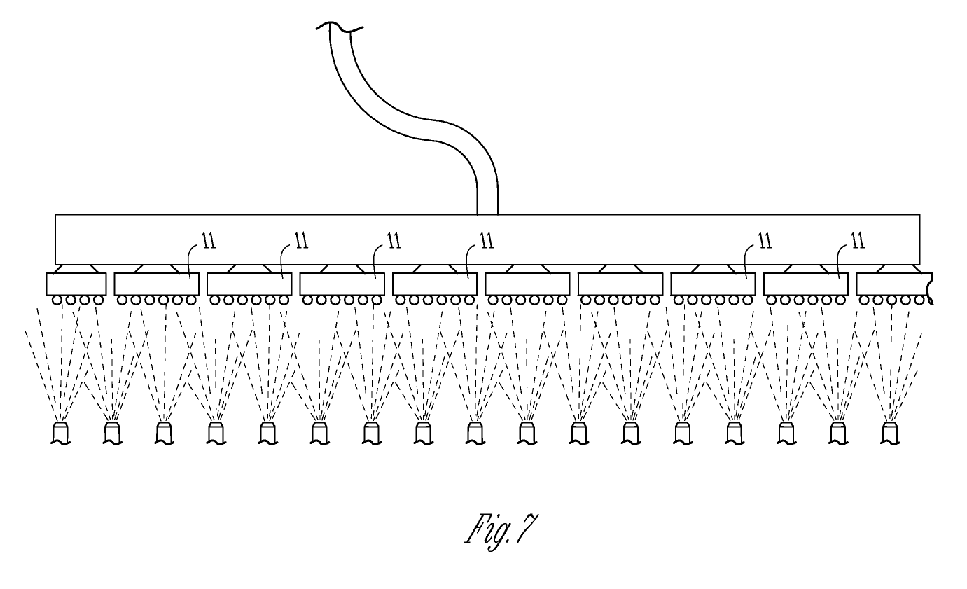

The method may further include (150) cleaning plurality of electronic components (11) (see FIGS. 6 and 7). The cleaning process that is utilized will depend in part on the type of adhesive. The cleaners may include solvents for thermoplastic or thermoset bond adhesives and/or hot water with a surfactant for environmentally friendly adhesives (e.g., wax).

It should be noted that the electronic components may be cleaned individually, or collectively, depending on when the electronic components (11) are picked from the carrier wafer (13). In addition, any cleaning may be done at a die level, wafer level or cleaning could be performed in a separate tray.

In some forms, (110) attaching a wafer (10) that includes a plurality of electronic components (11) to a carrier wafer (13) may include attaching a wafer (10) that includes integrated circuits on both sides of the wafer (10) (the FIGS. only show integrated circuits on one side of the wafer (10)). It should be noted that while the adhesive 14 is shown as being placed on the carrier wafer (13) in the FIGS., it is contemplated that the adhesive (14) may be initially placed on the wafer (10) and electronic components (11) before the wafer (10) is attached to the carrier wafer (13).

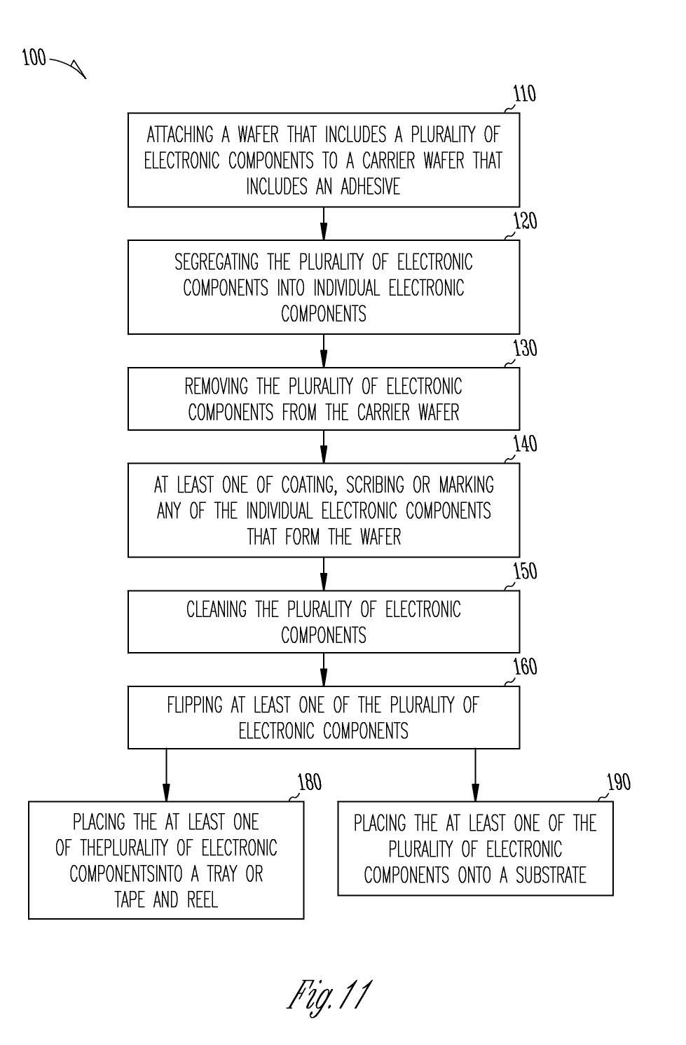

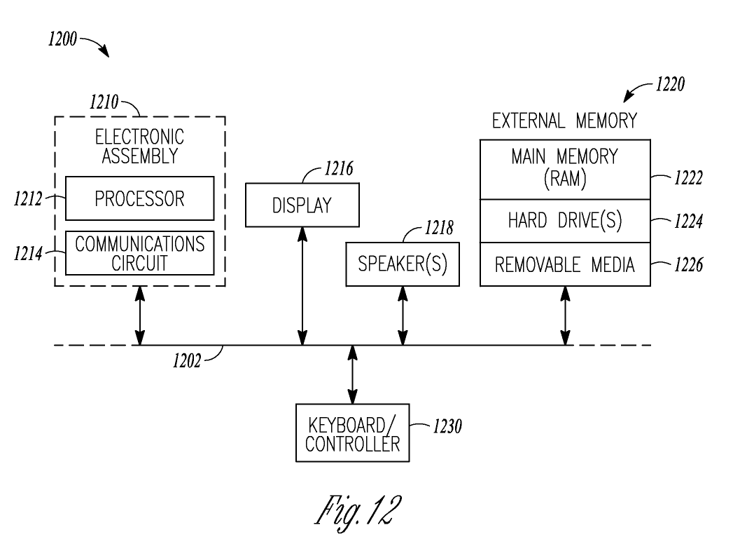

The method (100) may further include (160) flipping at least one of the plurality of electronic components (11); and [180] placing the at least one of the plurality of electronic components (11) into a tray T (see FIG. 10) or tape and reel R (see FIG. 9). In alternative forms, the method may include [190] placing the at least one of the plurality of electronic components (11) onto a substrate S (see FIG. 8).

It should be noted that the plurality of electronic components may be flipped individually, or collectively, using any equipment that is known now, or discovered in the future. The type of equipment that is used to flip the plurality of electronic components (11) will depend in part on the type, size and shape of the electronic components (11) as well as the application where the electronic components (11) are to be used (among other factors).

The type of tray T or tape and reel R that is used will also depend in part on the type, size and shape of the electronic components (11). In addition, the type of substrate S that is used in the method (100) will depend on the application where the electronic components (11) are to be used. It should be noted that each of the electronic components (11) may be placed onto one or more different types of substrates S.

FIG. 12 is a block diagram of an electronic apparatus 1200 incorporating at least one of the methods [100] described herein. Electronic apparatus 1200 is merely one example of an electronic apparatus in which forms of the methods [100] described herein may be used. Examples of an electronic apparatus 1200 include, but are not limited to, personal computers, tablet computers, mobile telephones, game devices, MP3 or other digital media players, etc.

In this example, electronic apparatus 1200 comprises a data processing system that includes a system bus 1202 to couple the various components of the electronic apparatus 1200. System bus 1202 provides communications links among the various components of the electronic apparatus 1200 and may be implemented as a single bus, as a combination of busses, or in any other suitable manner.

An electronic apparatus 1200 as describe herein may be coupled to system bus 1202. The electronic apparatus 1200 may include any circuit or combination of circuits. In one embodiment, the electronic apparatus 1200 includes a processor 1212 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that may be included in electronic apparatus 1200 are a custom circuit, an application-specific integrated circuit (ASIC), or the like, such as, for example, one or more circuits (such as a communications circuit 1214) for use in wireless devices like mobile telephones, tablet computers, laptop computers, two-way radios, and similar electronic systems. The IC can perform any other type of function.

The electronic apparatus 1200 may also include an external memory 1220, which in turn may include one or more memory elements suitable to the particular application, such as a main memory 1222 in the form of random access memory (RAM), one or more hard drives 1224, and/or one or more drives that handle removable media 1226 such as compact disks (CD), flash memory cards, digital video disk (DVD), and the like.

The electronic apparatus 1200 may also include a display device 1216, one or more speakers 1218, and a keyboard and/or controller 1230, which can include a mouse, trackball, touch pad, voice-recognition device, or any other device that permits a system user to input information into and receive information from the electronic apparatus 1200.

To better illustrate the methods [100] disclosed herein, a non-limiting list of examples is provided herein:

Example 1 includes a method of manufacturing ultra-thin wafers. The method includes attaching a wafer that includes a plurality of electronic components to a carrier wafer that includes an adhesive; segregating the plurality of electronic components into individual electronic components; and removing the plurality of electronic components from the carrier wafer.

Example 2 includes the method of example 1, wherein removing the plurality of electronic components from the carrier wafer includes removing individual electronic components from the carrier wafer.

Example 3 includes the method of any one of examples 1-2, wherein removing the plurality of electronic components from the carrier wafer includes simultaneously removing individual electronic components from the carrier wafer.

Example 4 includes the method of any one of examples 1-3, wherein segregating the plurality of electronic components into individual electronic components includes thinning the wafer.

Example 5 includes the method of any one of examples 1-4, wherein segregating the plurality of electronic components into individual electronic components includes dicing the wafer.

Example 6 includes the method of any one of examples 1-5, and further including at least one of coating, scribing or marking any of the individual electronic components that form the wafer.

Example 7 includes the method of any one of examples 1-6, and further including at least one of coating, scribing or marking the plurality of electronic components that form the wafer.

Example 8 includes the method of any one of examples 1-7, wherein removing the plurality of electronic components from the carrier wafer includes exposing the carrier wafer to ultraviolet radiation.

Example 9 includes the method of any one of examples 1-8, wherein removing the plurality of electronic components from the carrier wafer includes raising the temperature of the adhesive.

Example 10 includes the method of any one of examples 1-9, and further including cleaning the plurality of electronic components.

Example 11 includes the method of any one of examples 1-10, wherein attaching a wafer that includes a plurality of electronic components to a carrier wafer includes attaching a wafer that includes integrated circuits on both sides of the wafer.

Example 12 includes the method of any of examples 1-11, wherein attaching a wafer that includes a plurality of electronic components to a carrier wafer includes attaching the carrier wafer to an adhesive on the wafer.

Example 13 includes the method of any one of examples 1-12, and further including flipping at least one of the plurality of electronic components; and placing the at least one of the plurality of electronic components into a tray or tape and reel.

Example 14 includes the method of any one of examples 1-13, and further including flipping at least one of the plurality of electronic components; and placing the at least one of the plurality of electronic components onto a substrate.

Example 15 includes a method of manufacturing ultra-thin wafers. The method includes attaching a wafer that includes a plurality of electronic components to a carrier wafer that includes an adhesive; segregating the plurality of dice into individual electronic components, wherein segregating the plurality of dice into individual electronic components includes thinning and dicing the wafer; performing at least one of coating, scribing or marking any of the individual electronic components that form the wafer; and removing the plurality of electronic components from the carrier wafer, wherein removing the plurality of electronic components from the carrier wafer includes at least one of exposing the carrier to ultraviolet radiation or raising the temperature of the wafer.

Example 16 includes the method of example 15, wherein attaching a wafer that includes a plurality of electronic components to a carrier wafer includes attaching a wafer that includes integrated circuits on both sides of the wafer to the adhesive on the wafer.

Example 17 includes the method of any one of examples 15-16, and further including flipping at least one of the plurality of electronic components; and performing at least one of placing the at least one of the plurality of electronic components into a tray or tape and reel, or placing the at least one of the plurality of electronic components onto a substrate.

Example 18 includes a method of manufacturing ultra-thin wafers. The method includes attaching a wafer that includes a plurality of dice to a carrier wafer that includes an adhesive; segregating the plurality of dice into individual dies; and performing at least one of coating, scribing or marking any of the individual dies that form the wafer; cleaning the plurality of dice; and removing the plurality of dice from the carrier wafer.

Example 19 includes the method of example 18, wherein removing the plurality of electronic components from the carrier wafer includes simultaneously removing individual electronic components from the carrier wafer.

Example 20 includes the method of any one of examples 18-19, and further including flipping the at least one of the plurality of electronic components; and performing at least one of (i) placing at least one of the plurality of dice into a tray or tape and reel; and (ii) placing at least one of the plurality of electronic components onto a substrate.

This overview is intended to provide non-limiting examples of the present subject matter. It is not intended to provide an exclusive or exhaustive explanation. The detailed description is included to provide further information about the methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description.

The Abstract is provided to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1-20. (canceled)

21. A method comprising:
attaching a wafer that includes a plurality of electronic components to a carrier wafer that includes an adhesive;
segregating the plurality of electronic components into individual electronic components; and
removing the plurality of electronic components from the carrier wafer.

22. The method of claim 21, wherein removing the plurality of electronic components from the carrier wafer includes removing individual electronic components from the carrier wafer.

23. The method of claim 21, wherein removing the plurality of electronic components from the carrier wafer includes simultaneously removing individual electronic components from the carrier wafer.

24. The method of claim 21, wherein segregating the plurality of electronic components into individual electronic components includes thinning the wafer.

25. The method of claim 21, wherein segregating the plurality of electronic components into individual electronic components includes dicing the wafer.

26. The method of claim 21, further comprising at least one of coating, scribing or marking any of the individual electronic components that form the wafer.

27. The method of claim 21, further comprising at least one of coating, scribing or marking the plurality of electronic components that form the wafer.

28. The method of claim 23, wherein removing the plurality of electronic components from the carrier wafer includes exposing the carrier wafer to ultraviolet radiation.

29. The method of claim 21, wherein removing the plurality of electronic components from the carrier wafer includes raising the temperature of the adhesive.

30. The method of claim 21, further comprising cleaning the plurality of electronic components.

31. The method of claim 21, wherein attaching a wafer that includes a plurality of electronic components to a carrier wafer includes attaching a wafer that includes integrated circuits on both sides of the wafer.

32. The method of claim 21, wherein attaching a wafer that includes a plurality of electronic components to a carrier wafer includes attaching the carrier wafer to an adhesive on the wafer.

33. The method of claim 21, further comprising:
flipping at least one of the plurality of electronic components; and
placing the at least one of the plurality of electronic components into a tray or tape and reel.

34. The method of claim 21, further comprising:
flipping at least one of the plurality of electronic components; and
placing the at least one of the plurality of electronic components onto a substrate.

35. A method comprising:
attaching a wafer that includes a plurality of electronic components to a carrier wafer that includes an adhesive;
segregating the plurality of dice into individual electronic components, wherein segregating the plurality of dice into individual electronic components includes thinning and dicing the wafer;
performing at least one of coating, scribing or marking any of the individual electronic components that form the wafer; and
removing the plurality of electronic components from the carrier wafer, wherein removing the plurality of electronic components from the carrier wafer includes at least one of exposing the carrier to ultraviolet radiation or raising the temperature of the wafer.

36. The method of claim 35, wherein attaching a wafer that includes a plurality of electronic components to a carrier wafer includes attaching a wafer that includes integrated circuits on both sides of the wafer to the adhesive on the wafer.

37. The method of claim 35, further comprising:
flipping at least one of the plurality of electronic components; and
performing at least one of placing the at least one of the plurality of electronic components into a tray or tape and reel, or placing the at least one of the plurality of electronic components onto a substrate.

38. A method comprising:
attaching a wafer that includes a plurality of dice to a carrier wafer that includes an adhesive;
segregating the plurality of dice into individual dies; and
performing at least one of coating, scribing or marking any of the individual dies that form the wafer;
cleaning the plurality of dice; and
removing the plurality of dice from the carrier wafer.

39. The method of claim 38, wherein removing the plurality of electronic components from the carrier wafer includes simultaneously removing individual electronic components from the carrier wafer.

40. The method of claim 38, further comprising:
flipping the at least one of the plurality of electronic components; and
performing at least one of (i) placing at least one of the plurality of dice into a tray or tape and reel; and (ii) placing at least one of the plurality of electronic components onto a substrate.
